(19) United States
(12) Patent Application Publication
(10) Pub. No.: US 2026/0015216 A1
(43) Pub. Date: Jan. 15, 2026

(54) LIFT ATTACHMENT FOR TRANSPORTING SERVER RACKS

(71) Applicant: Jtec Industries, Inc., East Peoria, IL (US)

(72) Inventors: Joseph Knepp, Morton, IL (US); Nicholas Kaiser, Morton, IL (US); Jesse Schroeder, Peoria, IL (US)

(73) Assignee: Jtec Industries, Inc., East Peoria, IL (US)

(21) Appl. No.: 18/772,547

(22) Filed: Jul. 15, 2024

(51) Int. Cl. B66F 9/18; H05K 7/14

(52) U.S. Cl. CPC B66F 9/18; H05K 7/1488

(57) ABSTRACT

A lift attachment includes a first sidewall and a second sidewall, each of the first sidewall and the second sidewall being disposed in an upright position and substantially parallel to one another. The first sidewall and the second sidewall are spaced apart from one another and include inner surfaces that face one another and define a bay therebetween. The lift attachment further includes at least one lift plate having a ledge that extends from a bottom of the first sidewall and the second sidewall. The ledge includes an inner edge that defines an opening through a bottom of the lift attachment and through the entrance of the lift attachment. A connector of the lift attachment is configured to connect with a lifting mechanism of a lift truck such that the lift attachment moves up or down with the lifting mechanism.

### FIELD OF THE INVENTION

The present invention relates to transporting racks. The present invention also relates to transporting server racks in data centers.

### BACKGROUND OF THE INVENTION

Server racks are essential components in data centers, designed to house, organize, and protect servers and other network equipment. These racks ensure efficient use of space, facilitate cooling and airflow, and provide easy access for maintenance and upgrades. Typically, server racks conform to the EIA-310 standard, which ensures compatibility with a wide range of equipment. Server racks come in various sizes, commonly 42 U, 45 U, and 48 U, indicating the height of the rack. The depth of server racks also varies, typically ranging from 600 mm (23.6 inches) to 1200 mm (47.2 inches), to accommodate different server sizes and cabling requirements.

Server racks with wheels, often referred to as mobile server racks or rolling server racks, are designed for movement within data centers. These racks are equipped with casters, which are durable wheels that allow the rack to be rolled from one location to another. This mobility is useful during the initial setup of a data center, reconfiguration of server layouts, or when performing maintenance and upgrades that require equipment to be temporarily relocated.

In data centers, mobile server racks facilitate improved space management and adaptability to changing needs. However, when moving the mobile server racks, data center staff must manually reposition servers and networking equipment by pushing and pulling the server racks. Due to the large size and weight of server racks, manual movement by pushing and pulling the server racks can be difficult and the server racks are not easily maneuvered. Further, the mobile server racks typically have a low ground clearance from a bottom of the server rack to the floor. Due to the low ground clearance, forks of a fork lift cannot fit underneath the server rack, and thus fork lifts cannot currently be used to move server racks around a data center.

### SUMMARY OF THE INVENTION

A feature of the present invention is to provide a lift attachment that attaches to a lift truck for moving racks in an industrial setting.

Another feature of the present invention is to provide a lift attachment that attaches to a lift truck for moving server racks in a data center.

A further feature of the present invention is to provide a lift attachment that attaches to a fork truck for moving racks in an industrial setting.

An additional feature of the present invention is to provide an autonomous system including a lift attachment that attaches to an autonomous lift truck for moving racks in an industrial setting.

Another feature of the present invention is to provide a lift attachment that attaches to a lifting mechanism of a lift truck for moving racks in an industrial setting.

An additional feature of the present invention is to provide a method of moving server racks in an industrial setting.

Additional features and advantages of the present invention will be set-forth in part in the description that follows, and in part will be apparent from the description, or may be learned by practice of the present invention. The objectives and other advantages of the present invention will be realized and attained by means of the elements and combinations particularly pointed out in the description and appended claims.

To achieve these and other advantages, and in accordance with the purposes of the present invention, as embodied and broadly described herein, the present invention relates to a lift attachment that can be used with a lift truck in an industrial setting. The lift attachment includes a first sidewall and a second sidewall. Each of the first sidewall and the second sidewall are disposed in an upright position and substantially parallel to one another. The first sidewall and the second sidewall are spaced apart from one another and each of the first sidewall and the second sidewall include an inner surface that face one another and define a bay therebetween. The first sidewall and the second sidewall further define an entrance at a front end of the lift attachment. The lift attachment further includes at least one lift plate having a ledge that extends from a bottom of the first sidewall and the second sidewall. The ledge extends sideward into the bay at a substantially orthogonal direction relative to the first sidewall and the second sidewall. The ledge includes an inner edge that defines an opening through a bottom of the lift attachment and through the entrance of the lift attachment. The lift attachment further includes a connector configured to connect with a lifting mechanism of a lift truck such that the lift attachment moves up or down with the lifting mechanism.

The lift attachment can further include a back wall secured to the first sidewall and the second sidewall. The back wall is in the upright position and substantially orthogonal to the first sidewall, the second sidewall and the at least one lift plate. The back wall is situated at a rear end of the lift attachment. The ledge can run along the bottoms of the first sidewall, the back wall, and the second sidewall to define a U-shape.

The lift attachment can further include a plurality of wall guide members including at least one first sidewall guide member attached to the inner surface of the first sidewall, at least one second sidewall guide member attached to the inner surface of the second sidewall, and at least one back wall guide member attached to an inner surface of the back wall. The plurality of wall guide members are made of a material that is more flexible than the first sidewall, the second sidewall, and the back sidewall. For example, the plurality of guide members are made of a plastic or rubber material.

The at least one lift plate of the lift attachment can include at least one protective cover attached to an upper surface of the ledge. The at least one protective cover can be made of a metal material, such as steel. As an option, the protective cover can be made of a material that is more flexible than the ledge. For example, the at least one protective cover is made of a plastic or rubber material.

The lift attachment can further include a lock mechanism. The lock mechanism includes a gate pivotably coupled to a gate bracket. The gate is configured to pivot from an unlocked position at which the gate provides a clearance to the entrance, and a locked position at which the gate blocks at least a portion of the entrance.

The connector of the lift attachment can be configured to attach to a fork of a powered forklift or a manual forklift. The connector includes a first fork sleeve secured to the first sidewall and a second fork sleeve secured to the second sidewall. Each of the first fork sleeve and the second fork sleeve include an opening leading to a hollow center sized to receive a respective fork tine of the fork. The first fork sleeve is disposed at a bottom of the first sidewall and the second fork sleeve is disposed at a bottom of the second sidewall, and the upper surface of the ledge is disposed beneath the first fork sleeve and the second fork sleeve. A first plurality of angle brackets can connect an upper surface of the first fork sleeve to an outer surface of the first sidewall and a second plurality of angle brackets can connect an upper surface of the second fork sleeve to an outer surface of the second sidewall.

The lift attachment can include more than one bay. A divider wall can be disposed in between the first sidewall and the second sidewall. The divider wall and the first sidewall form the bay and the divider wall and the second sidewall form a second bay.

The present invention can further include a lift truck. The lift attachment can be attached to a lifting mechanism of the lift truck by the connector of the lift attachment. The lift truck can be a fork lift and the fork lift can be a powered forklift or a manual forklift.

The present invention can also include an autonomous lift truck including the lift attachment. The autonomous lift truck includes a drive train for moving the autonomous lift truck, a lifting mechanism secured to the connector of the lift attachment, a control unit configured to autonomously control the drive train based on signals received, and a sensor system configured to sense objects and send signals to the control unit. The drive train is configured to be controlled by the control unit to navigate autonomously within a building to a pick-up location and a drop off location.

The sensor system can be operatively connected to the lift attachment and the control unit can be further configured to autonomously control the lifting mechanism. The control unit can: (1) determine whether a rack is within the bay of the lift attachment at the pick-up location based on signals received from the sensor system; (2) activate the lifting mechanism such that the lift attachment elevates the rack to a raised position above a floor of the building at the pick up location; and (3) activate the lifting mechanism such that the lift attachment lowers the rack to a lowered position onto the floor of the building at the drop off location.

The lift attachment can further include a lock mechanism. The lock mechanism can include a gate pivotably coupled to a gate bracket. The gate is configured to pivot from an unlocked position at which the gate provides a clearance to the entrance, and a locked position at which the gate is pivoted towards the entrance and blocking at least a portion of the entrance. The locking mechanism includes an automated system electrically connected to a power source and the automated system is controlled by the control unit. At the pick-up location, when the control unit determines the rack is within the bay of the lift attachment, the control unit activates the locking mechanism to the locked position. When the control unit determines the autonomous lift truck is at the drop-off location and the lifting mechanism lowers the rack to the lowered position, the control unit activates the locking mechanism to the unlocked position.

The present invention can further include a method of transporting a server rack within an industrial setting. The method includes the steps of: attaching a lift attachment to a lifting mechanism of a lift truck, the lift attachment comprising a first sidewall, a second sidewall, and at least one lift plate comprising a ledge that extends from a bottom of the first sidewall and the second sidewall into a bay defined in between the first sidewall and the second sidewall; rolling a server rack comprising wheels into the bay of the lift attachment such that an outer perimeter of a bottom of the server rack is disposed above the ledge; raising the lifting mechanism of the lift truck such that the ledge of the lift attachment engages the perimeter of the bottom of the server rack and the wheels of the server rack are elevated above a floor of the industrial setting; and driving the lift truck and thereby transporting the server rack to a different location within the industrial setting.

It is to be understood that both the foregoing general description and the following detailed description are exemplary and explanatory only and intended to provide a further explanation of the present invention, as claimed.

### BRIEF DESCRIPTION OF THE DRAWINGS

The invention may be more fully understood with reference to the accompanying drawings. The drawings are intended to illustrate, not limit, the present teachings, according to an embodiment of the present invention.

FIG. 1 is a perspective view of a lift attachment, according to an embodiment of the present invention.

FIG. 2 is a top view of the lift attachment shown in FIG. 1.

FIG. 3 is a front view of the lift attachment shown in FIG. 1.

FIG. 4 is a right-side view of the lift attachment shown in FIG. 1

FIG. 5 is a rear view of the lift attachment shown in FIG. 1

FIG. 6 is a front perspective view of the lift attachment shown in FIG. 1, the lift attachment attached to an exemplary fork lift.

FIG. 7 is a rear perspective view of the lift attachment shown in FIG. 1, the lift attachment attached to an exemplary fork lift.

FIG. 8 is a front perspective view of the lift attachment shown in FIG. 1, the lift attachment attached to an exemplary fork lift and the lift attachment securing an exemplary server rack within.

FIG. 9A is a front view of the lift attachment shown in FIG. 1, the lift attachment attached to an exemplary fork lift and the lift attachment securing an exemplary server rack within.

FIG. 9B is a detail view of circle 9B of FIG. 9A.

FIG. 10 is a front view of a lift attachment, according to an embodiment of the present invention.

FIG. 11A is a top view of the lift attachment shown in FIG. 10.

FIG. 11B is a cross-sectional view taken along line 11B-11B of FIG. 11A.

FIG. 11C is a detail view of circle 11C of FIG. 11B.

FIG. 12 is a perspective view of a lift attachment attached to a lift truck, according to an embodiment of the present invention.

FIG. 13 is a side view of the lift attachment attached to the lift truck shown in FIG. 12.

FIG. 14 is a top view of the lift attachment attached to the lift truck shown in FIG. 12.

FIG. 15 is a front view of the lift attachment attached to the lift truck shown in FIG. 12.

### DETAILED DESCRIPTION OF THE INVENTION

According to one or more embodiments, the present invention includes a lift attachment. The lift attachment includes a first sidewall and a second sidewall, each of the first sidewall and the second sidewall being disposed in an upright position and substantially parallel to one another. The first sidewall and the second sidewall are spaced apart from one another. The first sidewall and the second sidewall each include an inner surface that face one another and define a bay therebetween. The first sidewall and the second sidewall further define an entrance at a front end of the lift attachment.

The lift attachment further includes at least one lift plate. The lift plate includes a ledge that extends from a bottom of the first sidewall and the second sidewall. The ledge extends sideward into the bay at a substantially orthogonal direction relative to the first sidewall and the second sidewall. The ledge includes an inner edge that defines an opening through a bottom of the lift attachment and through the entrance of the lift attachment. A connector is configured to connect with a lifting mechanism of a lift truck such that the lift attachment moves up or down with the lifting mechanism.

In certain embodiments, the lift attachment can further include a back wall secured to the first sidewall and the second sidewall. The back wall is in the upright position and substantially orthogonal to the first sidewall, the second sidewall, and the at least one lift plate. The back wall is situated at a rear end of the lift attachment, opposite the entrance.

A lift attachment having a back wall can be a unitary carriage, in which the first sidewall, the second sidewall, and the back wall are connected together by welding or other means of fixation, or are connected together by male and female connectors. Alternatively, the first sidewall, the second sidewall, and the back wall are formed from a unitary sheet of metal, or are formed by 3D printing.

A lift attachment without a back wall can include two separate pieces including the first sidewall and the second sidewall. Each of the first sidewall and the second sidewall can include a connector that attaches to the lifting mechanism of the lift truck. When the first sidewall and the second sidewall are attached to the lifting mechanism of the lift truck, the first sidewall and the second sidewall can be substantially parallel to one another and can form a bay therebetween.

The term ‘substantially parallel’ is defined herein as being parallel or within 5° of being parallel. The term ‘substantially orthogonal’ is defined herein as being orthogonal or within 5° of being orthogonal.

The lift attachment can be attached to a lifting mechanism of a lift truck by the connector. In certain embodiments, the lift attachment is connected to the lifting mechanism of the lift truck to move server racks within a data center. The lift attachment can also be used to move any type of rack, bin, container, pallet, box, and the like in any type of warehouse or industrial setting.

The first sidewall, the second sidewall, and the back wall can be dimensioned to accommodate different types of racks, such as different dimensioned server racks. The first sidewall, the second sidewall, and the back wall can include a height of from 10 inches to 40 inches, from 12 inches to 38 inches, from 14 inches to 36 inches, from 16 inches to 34 inches, from 18 inches to 32 inches, from 20 inches to 30 inches, from 22 inches to 28 inches, or from 24 inches to 26 inches.

The first sidewall, the second sidewall, and the back wall can be the same height or include any combination of the different heights previously described. In certain embodiments, the height of the first sidewall, the second sidewall, and/or the back wall can be adjustable. For example, the first sidewall, the second sidewall, and/or the back wall can be made of telescoping sheets of metal that can be adjusted to any of the different heights previously described and locked in place by a locking mechanism. The adjustments can be made based on the type of rack to be transported.

A width of the bay, i.e., a distance between the inner surfaces of the first sidewall and the second sidewall or the width of the back wall, can be dimensioned to accommodate different types of racks. The width of the bay can be from 10 inches to 50 inches, from 12 inches to 48 inches, from 14 inches to 46 inches, from 16 inches to 44 inches, from 18 inches to 42 inches, from 20 inches to 40 inches, from 22 inches to 38 inches, from 24 inches to 36 inches, from 26 inches to 34 inches, from 28 inches to 32 inches, or from 30 inches to 32 inches.

Server racks come in a variety of widths to accommodate different types of equipment and installation requirements. The width options can include 19-inch, 23-inch, 24-inch, 28-inch, and 32-inch racks. In certain embodiments, the width of the bay can be adjustable to accommodate different sized server racks. For example, the back wall can be made of telescoping sheets of metal that can be adjusted to any of the different widths of the bay previously described. Alternatively, the first sidewall and the second sidewall can independently be moved away from one another or towards one another along the lift attachment by sliding mechanisms, locking mechanisms, or other means of adjustment.

A depth of the bay, i.e., a length of the first sidewall and the second sidewall, can be dimensioned to accommodate different types of racks. The depth of the bay can be from 20 inches to 80 inches, from 25 inches to 75 inches, from 30 inches to 70 inches, from 35 inches to 65 inches, from 40 inches to 60 inches, from 45 inches to 55 inches, or from 48 inches to 52 inches.

Server racks come in a variety of depths to accommodate different types of equipment and installation requirements. The depth options range widely, including sizes such as 18 inches, 20 inches, 21 inches, 24 inches, 25 inches, 27 inches, 28 inches, 29 inches, 32 inches, 33 inches, 35 inches, 36 inches, 39 inches, 42 inches, 44 inches, 45 inches, 48 inches, 50 inches, 52 inches, and 60 inches.

In certain embodiments, the depth of the bay can be adjustable to accommodate different sized server racks. For example, each of the first sidewall and the second sidewall can be made of telescoping sheets of metal that can be adjusted to any of the different depths of the bay previously described. The first sidewall and the second sidewall can be extended or retract in length by other means of adjustment. For example, different sized extensions can be temporarily attached to the first sidewall and the second sidewall.

The lift attachment can include a plurality of wall guide members. The wall guide members can guide the rack within the bay of the lift attachment, and prevent damage to the rack and the lift attachment. The plurality of wall guide members can include at least one first sidewall guide member attached to the inner surface of the first sidewall, at least one second sidewall guide member attached to the inner surface of the second sidewall, and at least one back wall guide member attached to an inner surface of the back wall. In certain embodiments, the first sidewall, the second sidewall, and/or the back wall can include more than one wall guide member.

The plurality of wall guide members are made of a material that is more flexible than a material of the first sidewall, the second sidewall, and the back sidewall. For example, the first sidewall, the second sidewall, and the back wall can be made of a metal material or a hard plastic, while the wall guide members can be made of a softer or more deformable plastic or rubber material.

The plurality of wall guide members can be mechanically fixed to the inner surfaces of the first sidewall, the second sidewall, and/or the back wall, can be coated on the first sidewall, the second sidewall, and/or the back wall, or can be attached by other means. In certain embodiments, the wall guide members can be elongated and extend along the length of the first sidewall and the second sidewall. In certain embodiments, the wall guide members of the first sidewall and the second sidewall can taper towards the entrance of the bay, such that the guide members gradually reduce the width of the bay from a front of the lift attachment (entrance) towards a mid-portion of the bay. In such embodiments, the guide members guide the rack into the bay of the lift attachment.

As mentioned above, the lift attachment further includes at least one lift plate. The lift plate includes a ledge that extends from a bottom of the first sidewall and the second sidewall. In such embodiments, the at least one lift plate can include a first lift plate extending from the first sidewall and a second lift plate extending from the second sidewall. When the lift attachment includes a back wall, a back lift plate can extend from the back wall. In certain embodiments, the at least one lift plate can be a single lift plate including a ledge that runs along the bottoms of the first sidewall, the back wall, and the second sidewall, defining a U-shape.

The lift plate can have a very low ground clearance, i.e., a distance from a lower surface of the lift plate to a floor, such that the lift plate can fit underneath a low ground clearance server rack or other rack with low ground clearance. For example, the lower surface of the lift plate can have a ground clearance of from 0.1 inches to 1 inch, from 0.2 inches to 0.9 inches, from 0.3 inches to 0.8 inches, from 0.4 inches to 0.8 inches, or from 0.5 inches to 0.7 inches.

Further, the lift plate can be thin, yet sturdy, providing a low profile to fit under low ground clearance server racks. The height of the lift plate, i.e. a distance between an upper surface and a lower surface of the lift plate, can be from 0.5 inches to 2 inches, from 0.6 inches to 1.8 inches, from 0.7 inches to 1.6 inches, from 0.8 inches to 1.5 inches, from 0.9 inches to 1.4 inches, 1 inch to 1.3 inches, or from 1.1 inches to 1.2 inches.

Due the low ground clearance of the lift plate and the height of the lift plate, the lift plate is capable of fitting underneath a low ground clearance server rack. For example, a distance from the upper surface of the lift plate to the floor can be from 0.6 inches to 3 inches, from 0.8 inches to 2.7 inches, from 1 inch to 2.4 inches, from 1.2 inches to 2.1 inches, from 1.4 inches to 1.9 inches or from 1.5 inches to 1.7 inches.

The lift plate extends sideward into the bay of the lift attachment. The lift plate provides clearance such that a server rack can be rolled into the bay without interfering with the lift plate. A bottom perimeter of the server racks is typically in a close proximity to the server rack wheels. Accordingly, in certain embodiments, the lift plate can extend from 0.5 inches to 5 inches, from 1 inch to 4.5 inches, from 1.5 inches to 4 inches, from 2 inches to 3.5 inches, or from 2.5 inches to 3 inches into the bay from the respective sidewall and/or back wall, providing clearance for the wheels of the server rack.

In certain embodiments, the at least one lift plate can include at least one protective cover attached to an upper surface of the ledge. The protective cover prevents damage to the lift attachment and/or rack being transported by the lift attachment. The protective cover can also reinforce the ledge. As an option, the protective cover can be made a sturdy metal, such as steel.

As an option, the protective cover can be made of a material that is more flexible than the ledge. For example, the ledge can be made of a metal material or a hard plastic, while the protective cover can be made of a softer or more deformable plastic or rubber material. The protective cover can be mechanically fixed to the upper surface of the ledge, can be coated on the ledge, or can be attached by other means.

The height of the lift plate and the distances from the upper surface of the lift plate to the floor mentioned above can include the protective cover when present.

In certain embodiments, the one or more lift plates can be adjustable to accommodate different sized server racks. For example, the one or more lift plates can extend further inward towards a center of the bay and retract outward away from a center of the bay. In such embodiments, the lift plates can include sheets of metal that can be secured to the bottoms of the first sidewall, second sidewall, or back wall at different positions along its width.

In certain embodiments, the lift attachment can be modular such that different dimensioned lift plates can be attached thereto. For example, a first lift plate is attached/bolted to the lift attachment and can accommodate a server rack with a specified width and depth. To accommodate a different sized server rack, the first lift plate can be removed from the lift attachment and a second lift plate can be secured to the lift attachment that accommodates a server rack with a different specified width and depth. The different lifting plates provide a precise geometry for each different server rack size due to the limited distance between the server rack casters and the edges of the server rack frame (outer perimeter of the bottom of the server rack). Thus, many different sized lifting plates can be secured to the lift attachment to accommodate different sized server racks.

The present invention can further include a locking mechanism. The locking mechanism can lock the rack within the lift attachment, preventing the lift attachment from either rolling out of the lift attachment or falling out of the lift attachment while being transported. The lock mechanism can include a gate pivotably coupled to a gate bracket. The gate can be pivotably coupled to the gate bracket by a bolt, bearing, or the like. The gate is configured to pivot from an unlocked position at which the gate provides a clearance to the entrance, and a locked position at which the gate blocks at least a portion of the entrance. The gate can be deployed by a different mechanical means, such as by a sliding means and the like. For example, a sliding peg can slide through a channel of the first sidewall and/or the second sidewall to block at least a portion of the entrance.

In certain embodiments, the connector of the lift attachment is configured to attach to a fork of a powered forklift or a manually moveable forklift. In such embodiments, the connector includes a first fork sleeve and a second fork sleeve. The first fork sleeve can be secured to the first sidewall and the second fork sleeve can be secured to the second sidewall. Each of the first fork sleeve and the second fork sleeve include a respective opening leading to a respective hollow center sized to receive a respective fork tine of the fork. The first fork sleeve is disposed at a bottom of the first sidewall and the second fork sleeve is disposed at a bottom of the second sidewall.

As mentioned above, the lift plate is capable of fitting underneath a low ground clearance server rack. Thus, an upper surface of the lift plate or the ledge is disposed beneath the first fork sleeve and the second fork sleeve. In certain embodiments, the entire lift plate can be disposed underneath a bottom of the first and second fork sleeve. For example, a horizontal plane that intersects with a very bottom of the first and second fork sleeve may be above a horizontal plane that intersects with a very top of the lift plate. Alternatively, the lift plate may be substantially beneath the first and second sleeve, in which an upper portion of the lift plate is along the same horizontal plane as a lower portion of the first and second fork sleeve. In both embodiments, the upper surface of the lift plate is disposed entirely beneath an upper surface of the fork and fork sleeves. For example, a horizontal plane that intersects with a top surface of the fork or fork sleeve is above a horizontal plane that intersects with the top surface of the lift plate.

The present invention can further include angle brackets. A first plurality of angle brackets can connect an upper surface of the first fork sleeve to an outer surface of the first sidewall and a second plurality of angle brackets can connect an upper surface of the second fork sleeve to an outer surface of the second sidewall. The angle brackets further provide support to the sidewalls. While a lift truck moves and turns, weight from the racks can be applied to the sidewalls. The angle brackets provide additional support and prevent the lift attachment from failing.

The lift attachment can be attached to a lifting mechanism of a lift truck by other means. For example, the lift attachment can be directly connected to a carriage of a lift truck. In such embodiments, the lift attachment can include hooks that latch onto the carriage, such as upper and lower hooks. The hooks are designed to fit over the top and bottom crossbars of the carriage. The top hook of the lift attachment slides over the top bar of the carriage and the bottom hook fits under the bottom bar of the carriage. Locking pins can go through holes in the carriage and the hooks, locking the lift attachment to the lift truck. The lift truck can include a forklift with the forks removed. The lift attachment can be attached to the carriage of the lift truck by other means, such as locking plates, male and female connectors, and the like, as well as being permanently affixed thereto.

In certain embodiments, the lift attachment can have more than one bay. In such embodiments, the present invention can include one or more divider walls disposed in between the first sidewall and the second sidewall. If there is one divider wall, the divider wall and the first sidewall form the bay and the divider wall and the second sidewall form a second bay. The lift attachment of the present invention can have two bays, three bays, four bays, or more for transporting multiple racks at one time.

The present invention can include a lift truck having a lifting mechanism. The connector of the lift attachment, as described above, is connected to the lifting mechanism. The lift truck can be a forklift, a pallet jack, a reach truck, an order picker, a stacker, a turret truck, a side loader, a rough terrain forklift, a telehandler, a walkie stacker, an aisle master, a counterbalance forklift, a dockstocker truck, or any variation thereof. The lift truck can be powered or a manual truck. For example, a powered truck can include a power source, such as a battery or a combustion engine, that supplies power to and drives a drive train. The power source can also provide power to the lifting mechanism, such as power to a hydraulics system. Alternatively, the lift truck can be manually pushed and the lifting mechanism can be manually powered, the drive train of the lift truck can be powered by the power source and the lifting mechanism can be manually powered, or the lift truck can be manually pushed and the lifting mechanism can be powered by a power source.

In certain embodiments, the lift truck can be an autonomous lift truck. The autonomous lift truck includes: a drive train for moving the autonomous lift truck; a lifting mechanism secured to the connector of the lift attachment; a control unit configured to autonomously control the drive train based on signals received; and a sensor system configured to sense objects and send signals to the control unit. The drive train is configured to be controlled by the control unit to navigate autonomously within a building to a pick-up location and a drop off location.

The control unit of the autonomous lift truck is designed to process vast amounts of data in real-time to ensure safe and efficient operation. The control unit can be a high-performance central processing unit (CPU) or a combination of CPUs and graphics processing units (GPUs), which handle complex computations required for tasks such as sensor fusion, object detection, path planning, and decision making. These processors can be supported by large amounts of RAM and fast solid-state drives (SSDs) to store and quickly access the data needed for real-time processing.

The control unit can integrate with an array of sensors, including LiDAR, radar, cameras, and ultrasonic sensors, which provide a comprehensive view of the surroundings of the lift truck. The control unit can further include specialized hardware accelerators, such as field-programmable gate arrays (FPGAs) and application-specific integrated circuits (ASICs), to enhance the speed and efficiency of specific tasks, such as image recognition and data processing from the sensors. Connectivity hardware, including Ethernet ports and wireless communication modules, allows the control unit to communicate with other systems within the vehicle and external infrastructure.

Additionally, the control unit can be equipped with robust power management systems to ensure stable operation and redundancy features to enhance reliability and safety. This includes backup power supplies and fail-safe mechanisms that activate in the event of a hardware failure. Cooling systems, such as heat sinks and fans, can be used to maintain optimal operating temperatures. The control unit of the autonomous lift truck can include advanced processing power, comprehensive sensor integration, data storage, and safety features to enable autonomous driving.

In certain embodiments, the sensor system is operatively connected to the lift attachment and the control unit is further configured to autonomously control the lifting mechanism. In such embodiments, the control unit (1) determines whether a rack is within the bay of the lift attachment at the pick-up location based on signals received from the sensor system; (2) activates the lifting mechanism such that the lift attachment elevates the rack to a raised position above a floor of the building at the pick up location; and (3) activates the lifting mechanism such that the lift attachment lowers the rack to a lowered position onto the floor of the building at the drop off location.

In certain embodiments, the lift attachment further includes the locking mechanism as described in detail above. The locking mechanism can include an automated system electrically connected to a power source and the automated system is controlled by the control unit. In such embodiments, at the pick-up location, when the control unit determines the rack is within the bay of the lift attachment, the control unit activates the locking mechanism to the locked position. Further, when the control unit determines the autonomous lift truck is at the drop-off location and the lifting mechanism lowers the rack to the lowered position, the control unit activates the locking mechanism to the unlocked position.

The present invention further includes a method of transporting a server rack within an industrial setting such as a data center. The method includes the steps of: attaching a lift attachment to a lifting mechanism of a lift truck, such as forks of a forklift, the lift attachment including a first sidewall, a second sidewall, and at least one lift plate comprising a ledge that extends from a bottom of the first sidewall and the second sidewall into a bay defined in between the first sidewall and the second sidewall; rolling a server rack comprising wheels into the bay of the lift attachment such that an outer perimeter of a bottom of the server rack is disposed above the ledge; raising the forks of the forklift such that the ledge of the lift attachment engages the perimeter of the bottom of the server rack and the wheels of the server rack are elevated above a floor of the data center; and driving the forklift and thereby transporting the server rack to a different location within the data center. The method can incorporate any of the features described herein.

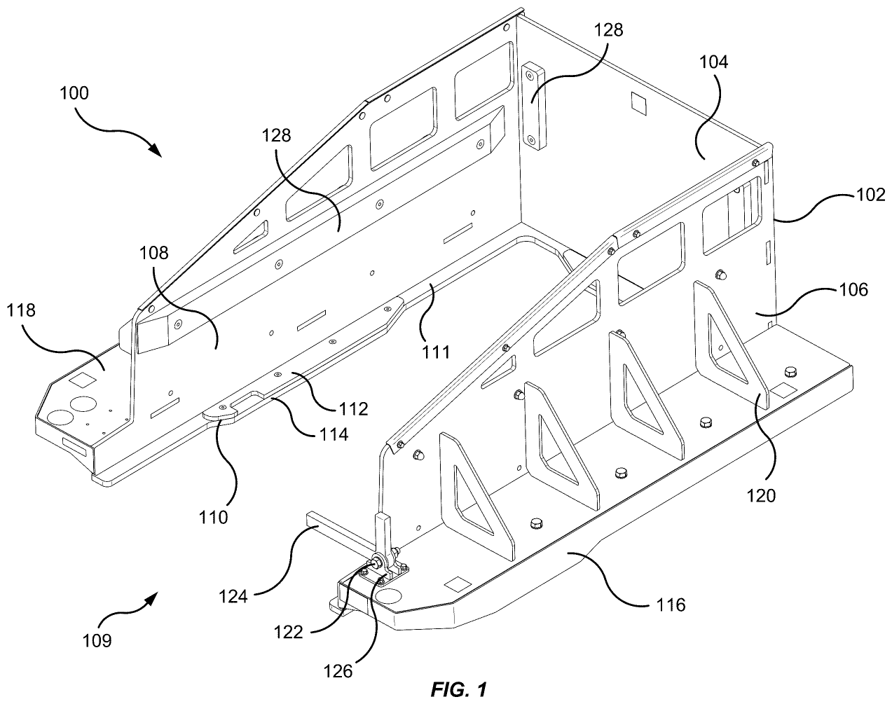

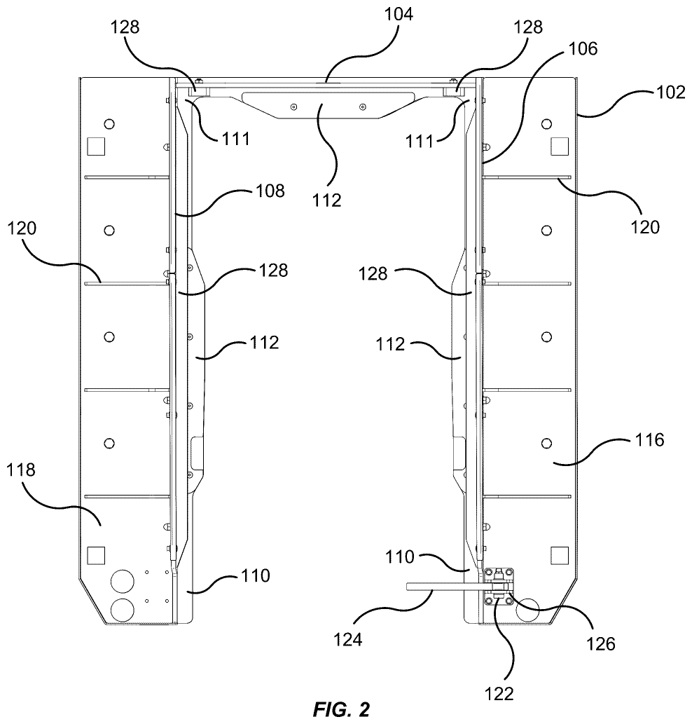

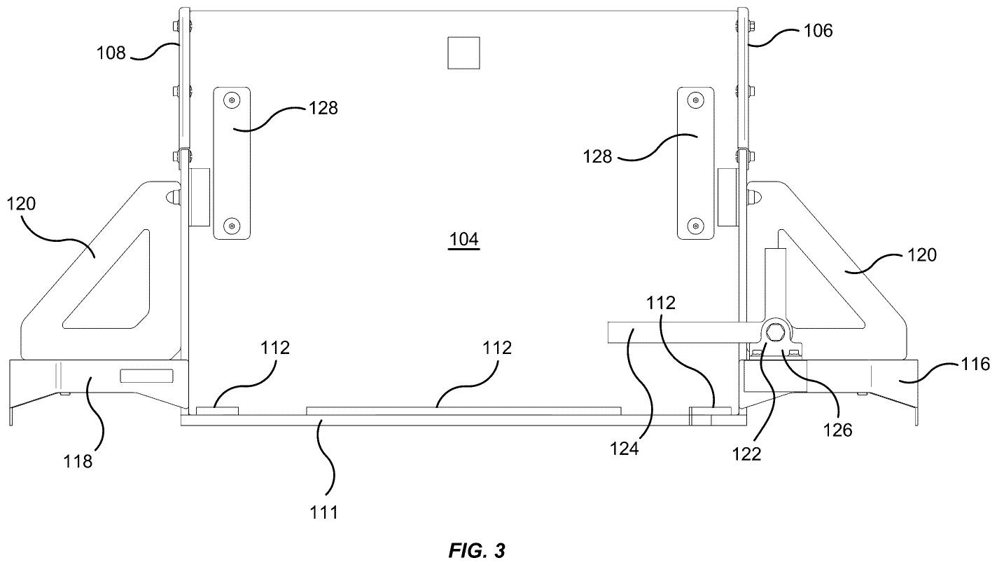

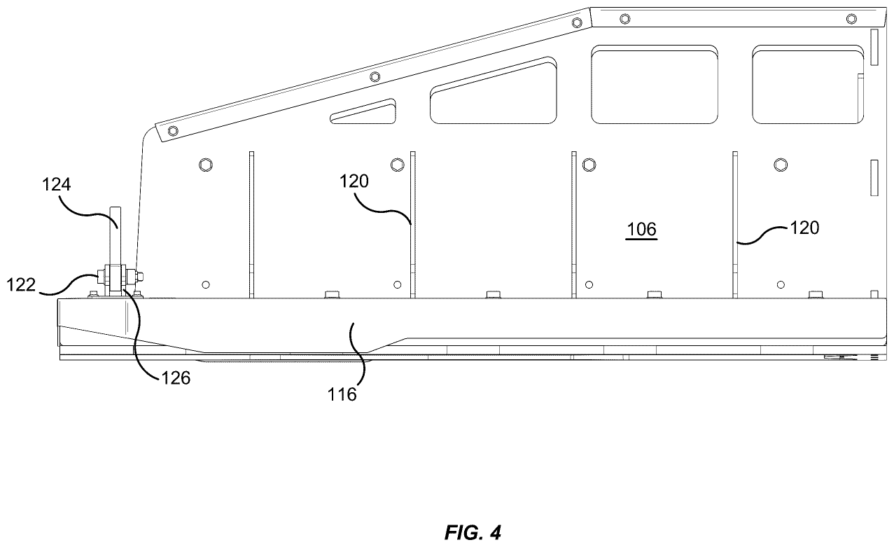

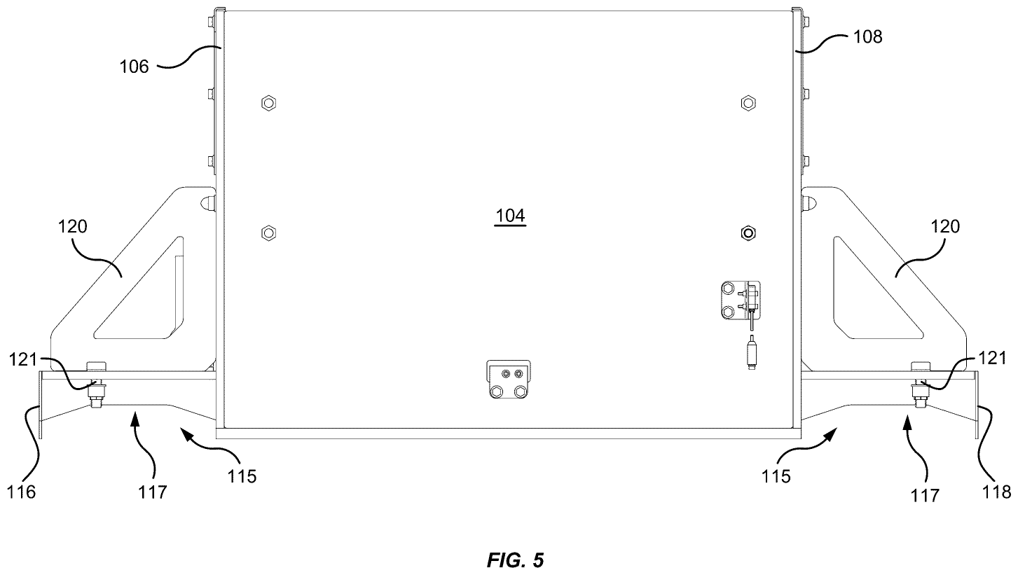

With reference now to the drawings, FIG. 1 is a perspective view of a lift attachment 100, according to an embodiment of the present invention. FIG. 2 is a top view of the lift attachment 100 shown in FIG. 1. FIG. 3 is a front view of the lift attachment 100 shown in FIG. 1. FIG. 4 is a right-side view of the lift attachment 100 shown in FIG. 1. FIG. 5 is a rear view of the lift attachment 100 shown in FIG. 1. The lift attachment 100 of FIGS. 1-5 is a forklift attachment 102.

The forklift attachment 102 includes a back wall 104, a first sidewall 106, and a second sidewall 108. Each of the first sidewall 106 and the second sidewall 108 are disposed in an upright position and substantially parallel to one another. The first sidewall 106 and the second sidewall 108 are spaced apart from one another. The first sidewall 106 and the second sidewall 108 each include an inner surface that face one another and define a bay therebetween. The first sidewall 106 and the second sidewall 108 further define an entrance 109 at a front end of the lift attachment 100. The back wall 104 is secured to the first sidewall 106 and the second sidewall 108. The back wall 104 is in the upright position and substantially orthogonal to the first sidewall 106 and the second sidewall 108. The back wall 104 is situated at a rear end of the lift attachment 100. Thus, the back wall 104, the first sidewall 106, and the second sidewall 108 form a rectangular cuboid shape with an open front end.

The lift attachment 100 includes at least one lift plate 110. As shown in FIG. 2, the at least one lift plate 110 includes a single lift plate 110 that runs along the bottoms of the first sidewall 106, the back wall 104, and the second sidewall 108, and defines a U-shape. The lift plate 110 includes a ledge 111 that extends from a bottom of the first sidewall 106, the second sidewall 108, and the back wall 104. The ledge 111 extends sideward into the bay at a substantially orthogonal direction relative to the first sidewall 106, the second sidewall 108, and the backwall 104. The ledge 111 includes an inner edge 114 that defines an opening through a bottom of the lift attachment 100 and through the entrance 109 of the lift attachment 100.

The lift plate 110 can further include at least one protective cover 112 attached to an upper surface of the ledge 111. As can be seen, protective covers 112 are attached to the ledge 111 adjacent to the first sidewall 106, adjacent to the second sidewall 108, and adjacent to the back wall 104. The protective covers 112 are made of a material that is more flexible than the ledge 111. For example, the ledge 111 can be made of a metal material and the protective covers 112 can be made of a plastic or rubber material. The protective covers 112 prevent damage to the lift attachment 100 and the server racks.

The lift attachment 100 includes a connector 116, 118 configured to connect with a lifting mechanism of a lift truck such that the lift attachment 100 moves up or down with the lifting mechanism. The connector 116, 118 of the forklift attachment 102 is configured to attach to a fork of a forklift. The connector 116, 118 includes a first fork sleeve 116 secured to the first sidewall 106 and a second fork sleeve 118 secured to the second sidewall 108. Each of the first fork sleeve 116 and the second fork sleeve 118 include an opening 115 leading to a hollow center 117 sized to receive a respective fork tine of the fork. A lock bolt 121 or other locking mechanism can lock the first and second fork sleeves 116, 118 to the fork of a fork lift. The first fork sleeve 116 is disposed at a bottom of the first sidewall 106 and the second fork sleeve 118 is disposed at a bottom of the second sidewall 108. An upper surface of the ledge 111 is disposed beneath the first fork sleeve 116 and the second fork sleeve 118, providing a low clearance to fit underneath the low ground clearance of a server rack.

The lift attachment 100 can further include a plurality of angle brackets 120. As can be seen, four angle brackets 120 can connect an upper surface of the first fork sleeve 116 to an outer surface of the first sidewall 106 and four angle brackets 120 can connect an upper surface of the second fork sleeve 118 to an outer surface of the second sidewall 108. The angel brackets 120 provide support to the lift attachment 100, such that the first sidewall 106 and the second sidewall 108 can handle an increased load when moving server racks. When the lift attachment 100 is moving, the server rack can shift from side to side. The angle brackets 120 prevent the lift attachment 100 from failing. Each side can have one, two, three, four, five, six, or more angle brackets 120.

The lift attachment 100 can further include a plurality of wall guide members 128. Wall guide members 128 can be attached to the inner surface of the first sidewall 106, the inner surface of the second sidewall 108, and/or the inner surface of the back wall 104. As can be seen, the wall guide members 128 attached to the first sidewall 106 and the second sidewall 108 can include a taper that tapers to a thinner profile towards the entrance 109. This allows a server rack, or any other type of rack, to be guided through the entrance 109 and into the bay. The wall guide members 128 are made of a material that is more flexible than the first sidewall 106, the second sidewall 108, and the back wall 104. For example, the sidewalls 106, 108 and back wall 104 can be made of a metal material and the wall guide members 128 can be made of a plastic or rubber material. The wall guide members 128 guide the racks and prevent damage to the racks and the lift attachment 100.

The lift attachment 100 can further include a lock mechanism 122. The lock mechanism 122 can lock the server rack or other type of rack within the bay of the lift attachment 100. The lock mechanism 122 can include a gate 124 and a gate bracket 126. The gate bracket 126 can be attached to one or both of the first fork sleeve 116 and the second fork sleeve 118. The gate 124 can be pivotably secured to the gate bracket 126 and thus can pivot upwards and downwards. For example, the gate 124 can be secured to the gate bracket 126 by a bolt and can pivot about the bolt. The gate 124 can be secured to the gate bracket 126 by the bolt with some resistance to pivoting. Thus, when the gate 124 is pivoted, the gate 124 can stay in place until a threshold force is acted upon the gate 124 to pivot in the opposite direction. The gate 124 is configured to pivot from an unlocked position at which the gate 124 provides a clearance to the entrance 109, and a locked position at which the gate 124 blocks at least a portion of the entrance 109. The gate 124 can be an L-shaped member and thus can include a lever to allow the gate 124 to be easily pivoted back and forth.

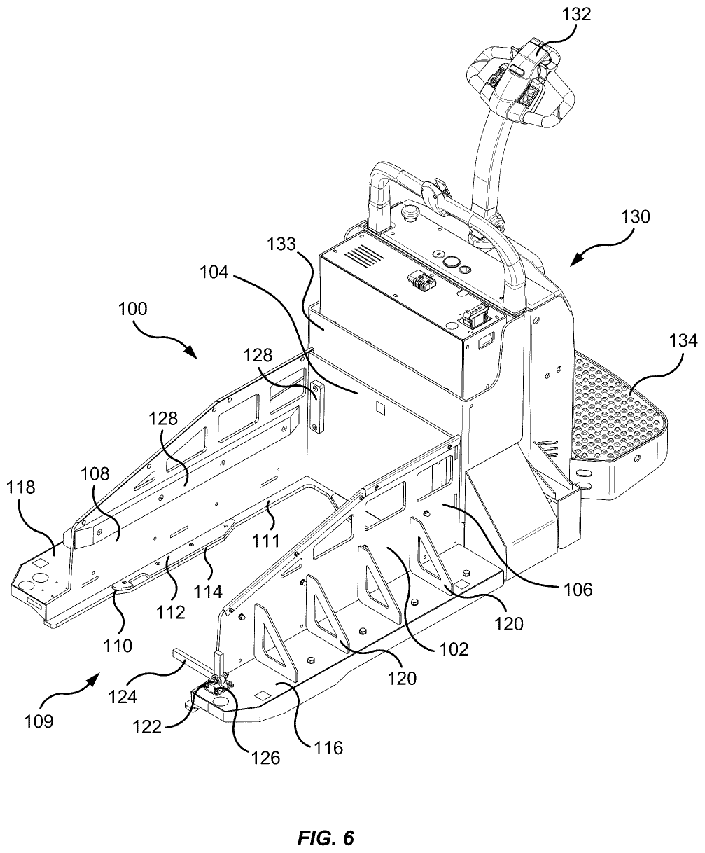

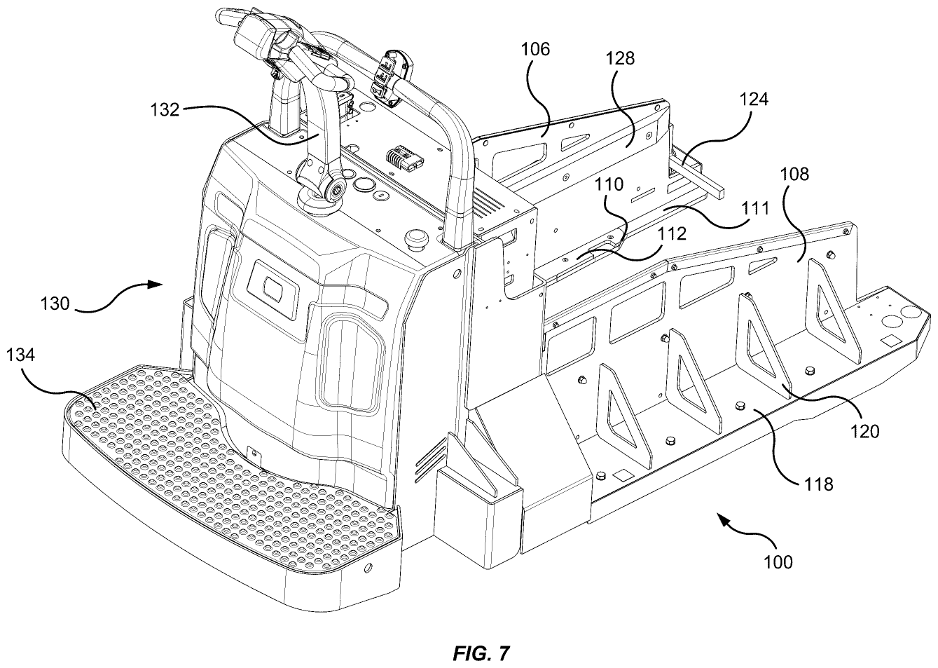

FIG. 6 is a front perspective view of the lift attachment 100 shown in FIG. 1, the lift attachment 100 attached to an exemplary fork lift 130. FIG. 7 is a rear perspective view of the lift attachment 100 shown in FIG. 1, the lift attachment 100 attached to an exemplary fork lift 130.

As illustrated in FIGS. 6 and 7, the lift attachment 100 is the forklift attachment 102 including the back wall 104, the first sidewall 106, the second sidewall 108, the lift plate 110, and the connector 116, 118. The inner surfaces of the first sidewall 106, the second sidewall 108, and the back wall 104 define the bay therebetween and the entrance 109 to the bay. The lift plate 110 includes the ledge 111, the protective cover 112, and the inner edge 114 that defines the opening. The guide members 128 are attached to the inner surfaces of the first sidewall 106, the second sidewall 108, and the back wall 104. The connectors 116, 118 include the first sleeve 116 and the second sleeve 118. The support members 120 are secured to the upper surfaces of the first sleeve 116 and the second sleeve 118 and the outer surfaces of the first sidewall 106 and second sidewall 108, respectively. The lift attachment 100 further includes the lock mechanism 122 including the gate 124 and the gate bracket 126. The lock mechanism 122 is shown in the locked position.

The lift attachment 100 is illustrated as being attached to a forklift 130 having controls 132 and a platform 134. The forklift 130 includes a fork (not shown) having two fork tines. One of the fork tines is inserted into the first sleeve 116 and the other of the fork tines is inserted into the second sleeve 118. The fork is secured to a lifting mechanism 133 of the forklift 130. The controls 132 allow a user to driver and steer the forklift 130 as well as raise and lower the lifting mechanism 133. Accordingly, a server rack can be pushed into the bay, the locking mechanism 122 can be placed in the lock position, and the forklift 130 can be controlled to activate the lifting mechanism 133 to raise the server rack above the floor. The driver of the forklift 130 can drive to a different location in the data center, and thereby transport the server rack within the data center.

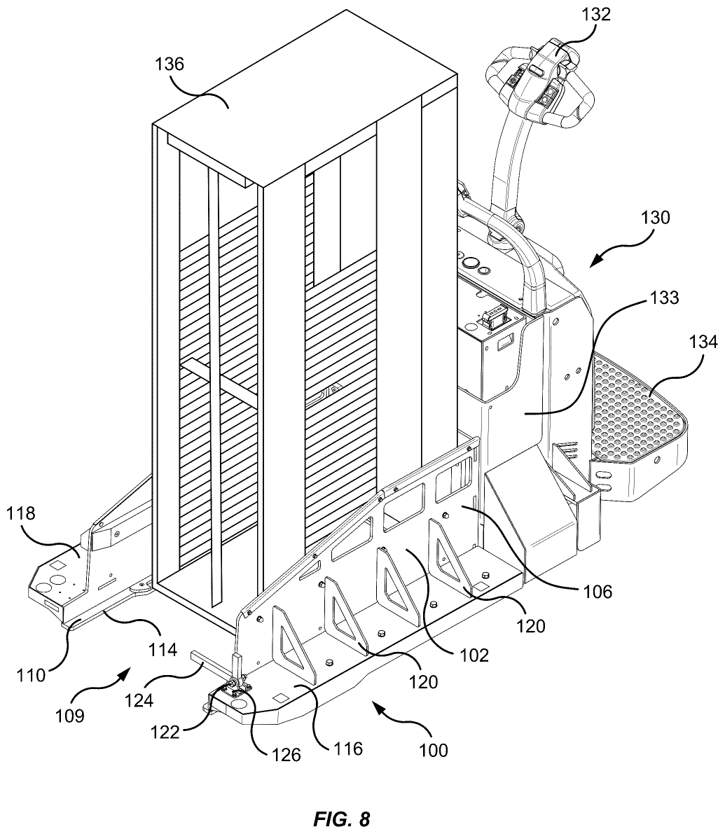

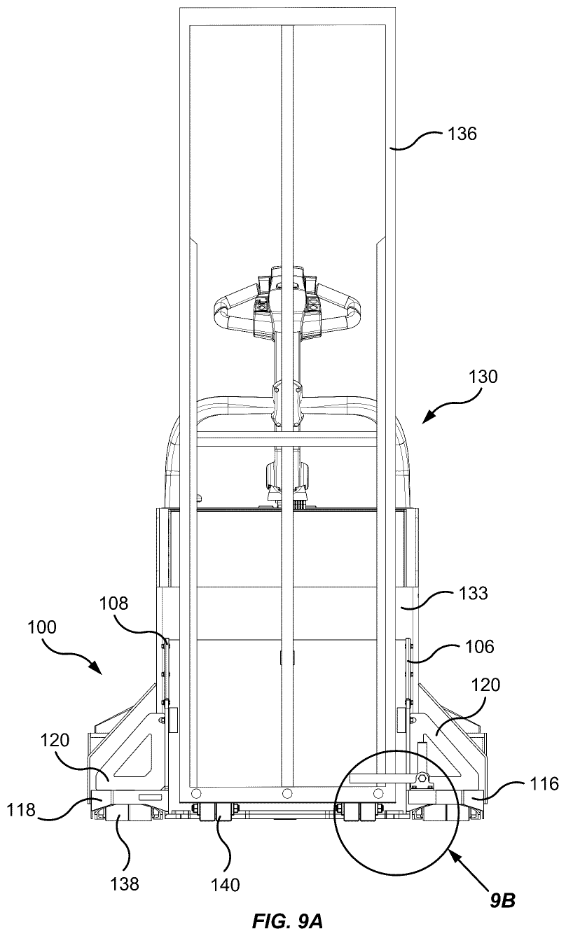

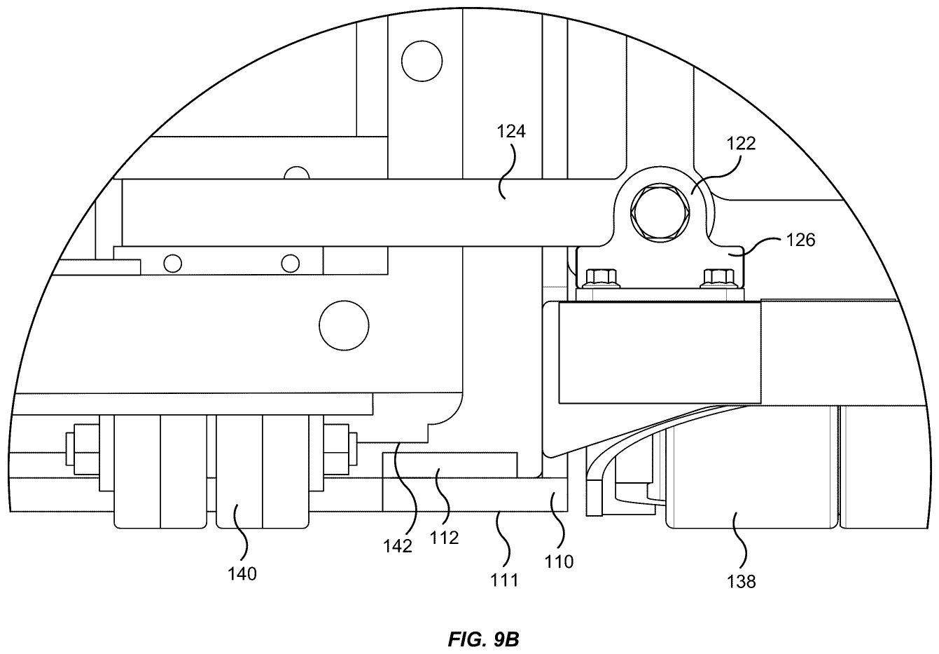

FIG. 8 is a front perspective view of the lift attachment 100 shown in FIG. 1, the lift attachment 100 attached to an exemplary fork lift 130 and the lift attachment 100 securing an exemplary server rack 136 within. FIG. 9A is a front view of the lift attachment 100 shown in FIG. 1, the lift attachment 100 attached to the exemplary fork lift 130 and the lift attachment 100 securing an exemplary server rack within 136. FIG. 9B is a detail view of circle 9B of FIG. 9A.

As illustrated in FIGS. 8-9B, the lift attachment 100 is the forklift attachment 102 including the back wall (not shown), the first sidewall 106, the second sidewall 108, the lift plate 110, and the connector 116, 118. The inner surfaces of the first sidewall 106, the second sidewall 108, and the back wall 104 define the bay therebetween and the entrance 109 to the bay. The lift plate 110 includes the ledge 111, the protective cover 112, and the inner edge 114 that defines the opening. The guide members (not shown) are attached to the inner surfaces of the first sidewall 106, the second sidewall 108, and the back wall 104. The connectors 116, 118 include the first sleeve 116 and the second sleeve 118. The support members 120 are secured to the upper surface of the first sleeve 116 and the second sleeve 118 and the outer surfaces of the first sidewall 106 and second sidewall 108, respectively. The lift attachment 100 further includes the lock mechanism 122 including the gate 124 and the gate bracket 126. The lock mechanism 122 is shown in the locked position.

The lift attachment 100 is illustrated as being attached to the forklift 130 having the controls 132, the platform 134, and wheels 138. The forklift 130 includes a fork (not shown) having two fork tines. One of the fork tines is inserted into the first sleeve 116 and the other of the fork tines is inserted into the second sleeve 118. The fork is secured to the lifting mechanism 133 of the forklift 130. The controls 132 allows a user to driver and steer the forklift 130 as well as raise and lower the lifting mechanism 133. A server rack 136 is shown to be within the bay of the lift attachment 100. The locking mechanism 122 is in the locked position, securing the server rack 136 within the bay.

FIGS. 9A and 9B show the server rack 136 having casters 140 within the bay of the lift attachment 100 prior to the lifting mechanism 133 being activated to lift the server rack 136 to an elevated position. As illustrated in FIG. 8B, the server rack 136 has a bottom outer perimeter 142. Due to the opening defined by the inner edge 114 of the ledge 111, the server rack 136 with casters 140 can be pushed within the bay such that the first sidewall 106 and the second sidewall 108 are adjacent to the sidewalls of the server rack 136. Due to the low profile and low clearance of the lift plate 110, the lift plate 110 can fit underneath the bottom outer perimeter 142 of the server rack 136. The forklift 130 can be controlled to activate the lifting mechanism 133 to raise the lift attachment 100 that engages the bottom outer perimeter 142 of the server rack, and in turn, raises the server rack 136 above the floor, elevating the casters 140 above the floor. The driver of the forklift 130 can drive to a different location in the data center, and thereby transport the server rack 136 within the data center.

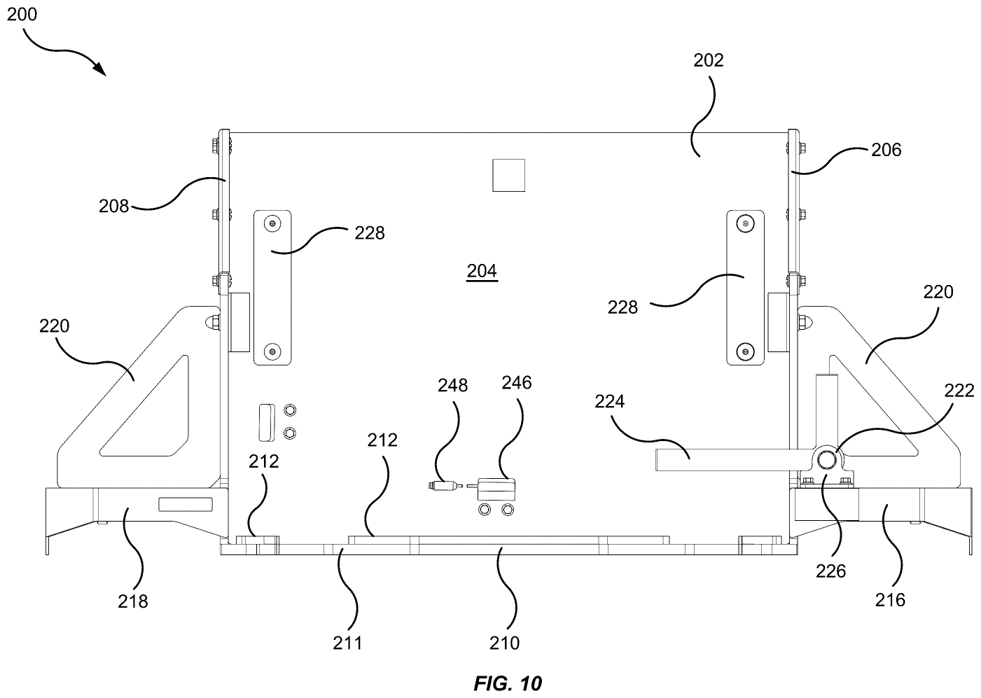

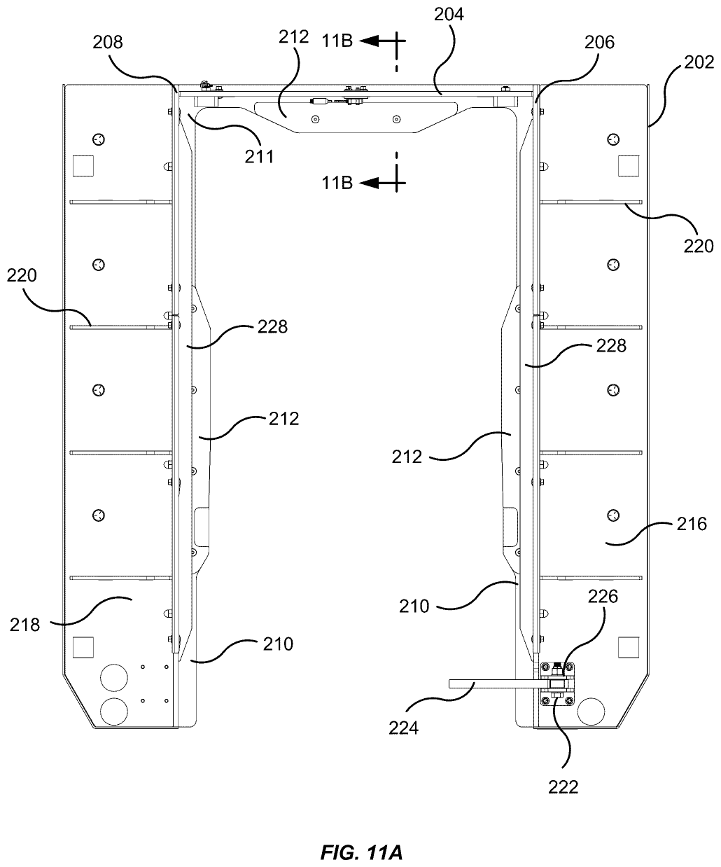

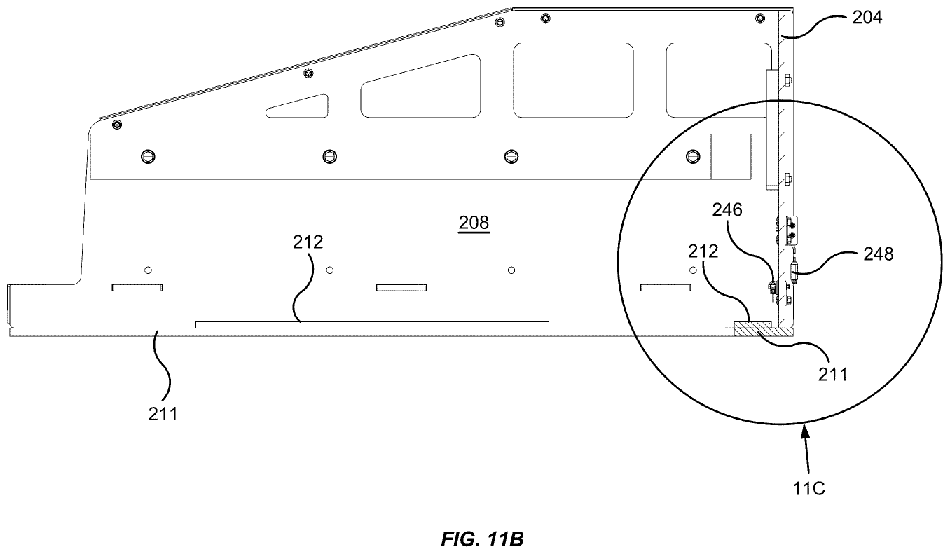

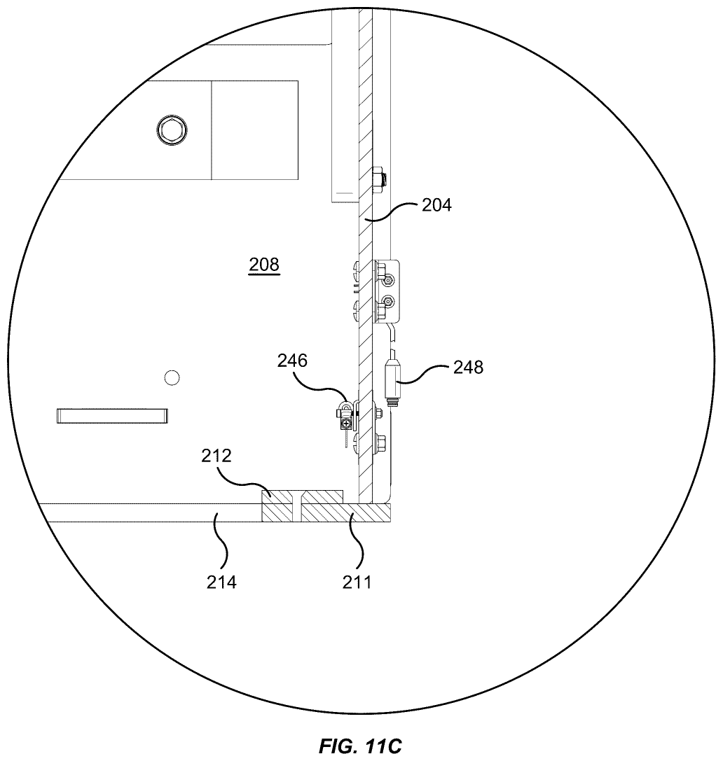

FIG. 10 is a front view of a lift attachment 200, according to another embodiment of the present invention. FIG. 11A is a top view of the lift attachment 200 shown in FIG. 10. FIG. 11B is a cross-sectional view taken along line 11B-11B of FIG. 11A. FIG. 11C is a detail view of circle 11C of FIG. 11B. The lift attachment 200 can be part of an automated system, an autonomous system, a semi-automated system, or a semi-autonomous system. The lift attachment 200 of FIGS. 10-11C is a forklift attachment 202.

The forklift attachment 202 includes a back wall 204, a first sidewall 206, and a second sidewall 208. Each of the first sidewall 206 and the second sidewall 208 are disposed in an upright position and substantially parallel to one another. The first sidewall 206 and the second sidewall 208 are spaced apart from one another. The first sidewall 206 and the second sidewall 208 each include an inner surface that face one another and define a bay therebetween. The first sidewall 206 and the second sidewall 208 further define an entrance at a front end of the lift attachment 200. The back wall 204 is secured to the first sidewall 206 and the second sidewall 208. The back wall 204 is in the upright position and substantially orthogonal to the first sidewall 206 and the second sidewall 208. The back wall 204 is situated at a rear end of the lift attachment 200. Thus, the back wall 204, the first sidewall 206, and the second sidewall 208 form a rectangular cuboid shape with an open front end.

The lift attachment 200 includes at least one lift plate 210. As shown in FIG. 11A, the at least one lift plate 210 includes a single lift plate 210 that runs along the bottoms of the first sidewall 206, the back wall 204, and the second sidewall 208, and defines a U-shape. The lift plate 210 includes a ledge 211 that extends from a bottom of the first sidewall 206, the second sidewall 208, and the back wall 204. The ledge 211 extends sideward into the bay at a substantially orthogonal direction relative to the first sidewall 206, the second sidewall 208, and the backwall 204. The ledge 211 includes an inner edge 214 that defines an opening through a bottom of the lift attachment 200 and through the entrance of the lift attachment 200.

The lift plate 210 can further include at least one protective cover 212 attached to an upper surface of the ledge 211. As can be seen, protective covers 212 are attached to the ledge 211 adjacent to the first sidewall 206, adjacent to the second sidewall 208, and adjacent to the back wall 204. The protective covers 212 are made of a material that is more flexible than the ledge 211. For example, the ledge 211 can be made of a metal material and the protective covers 212 can be made of a plastic or rubber material. The protective covers 212 prevent damage to the lift attachment 200 and the server racks.

The lift attachment 200 includes a connector 216, 218 configured to connect with a lifting mechanism of a lift truck such that the lift attachment 200 moves up or down with the lifting mechanism. The connector 216, 218 of the forklift attachment 202 is configured to attach to a fork of a forklift. The connector 216, 218 includes a first fork sleeve 216 secured to the first sidewall 206 and a second fork sleeve 218 secured to the second sidewall 208. Each of the first fork sleeve 216 and the second fork sleeve 218 include an opening leading to a hollow center sized to receive a respective fork tine of the fork. The first fork sleeve 216 is disposed at a bottom of the first sidewall 206 and the second fork sleeve 218 is disposed at a bottom of the second sidewall 208. An upper surface of the ledge 211 is disposed beneath the first fork sleeve 216 and the second fork sleeve 218, providing a low clearance to fit underneath the low ground clearance of a server rack.

The lift attachment 200 can further include a plurality of angle brackets 220. As can be seen, four angle brackets 220 can connect an upper surface of the first fork sleeve 216 to an outer surface of the first sidewall 206 and four angle brackets 220 can connect an upper surface of the second fork sleeve 218 to an outer surface of the second sidewall 208. The angel brackets 220 provide support to the lift attachment 200, such that the first sidewall 206 and the second sidewall 208 can handle an increased load when moving server racks. When the lift attachment 200 is moving, the server rack can shift from side to side. The angle brackets 220 prevent the lift attachment 200 from failure. Each side can have one, two, three, four, five, six, or more angle brackets 220.

The lift attachment 200 can further include a plurality of wall guide members 228. Wall guide members 228 can be attached to the inner surface of the first sidewall 204, the inner surface of the second sidewall 208, and the inner surface of the back wall 204. As can be seen, the wall guide members 228 attached to the first sidewall 204 and the second sidewall 208 can include a taper that tapers to a thinner profile towards the entrance. This allows a server rack, or any other type of rack, to be guided through the entrance and into the bay. The wall guide members 228 are made of a material that is more flexible than the first sidewall 206, the second sidewall 208, and the back sidewall 204. For example, the sidewalls 206, 208 and backwall 204 can be made of a metal material and the guide members 228 can be made of a plastic or rubber material. The guide members 228 guide the racks and prevent damage to the racks and the lift attachment 200.

The lift attachment 200 can further include a lock mechanism 222. The lock mechanism 222 can lock the server rack or other type of rack within the bay of the lift attachment 200. The lock mechanism 212 can include a gate 224 and a gate bracket 226. The gate bracket 226 can be attached to one of the first fork sleeve 216 and the second fork sleeve 218. The gate 224 can be pivotably secured to the gate bracket 226 and thus can pivot upwards and downwards. For example, the gate 224 can be secured to the gate bracket 226 by a bolt and can pivot about the bolt. The gate 224 can be secured to the gate bracket 226 by the bolt with some resistance to pivoting. Thus, when the gate 224 is pivoted, the gate 224 can stay in place until a threshold force is acted upon the gate 224 to pivot in the opposite direction. The gate 224 is configured to pivot from an unlocked position at which the gate 224 provides a clearance to the entrance 209, and a locked position at which the gate 224 blocks at least a portion of the entrance 209. The gate 224 can be an L-shaped member and thus can include a lever to allow the gate 224 to be easily pivoted back and forth.

FIGS. 10-11C further illustrate a sensor system 246, 248. The sensor system 246, 248 can include one or more sensors 246 secured within the bay or at other locations of the lift attachment 200. The sensor system 246, 248 further includes an electrical connection 248 that can connect with a computing system or control unit of the lift truck to provide power to the sensors 246 and to transmit data from the sensors 246 to the computing system. In certain embodiments, a power connection can be connected to an actuator of the locking mechanism 224. When the one or more sensors 246 sense that a server rack or other type of rack is fully within the bay of the lift attachment 200, data can be transferred from the sensors 246 to the computing system to indicate that the bay is loaded and ready to raise. The computing system can automatically close the gate 224 of the lock mechanism 226 and raise the lifting mechanism of the lift truck.

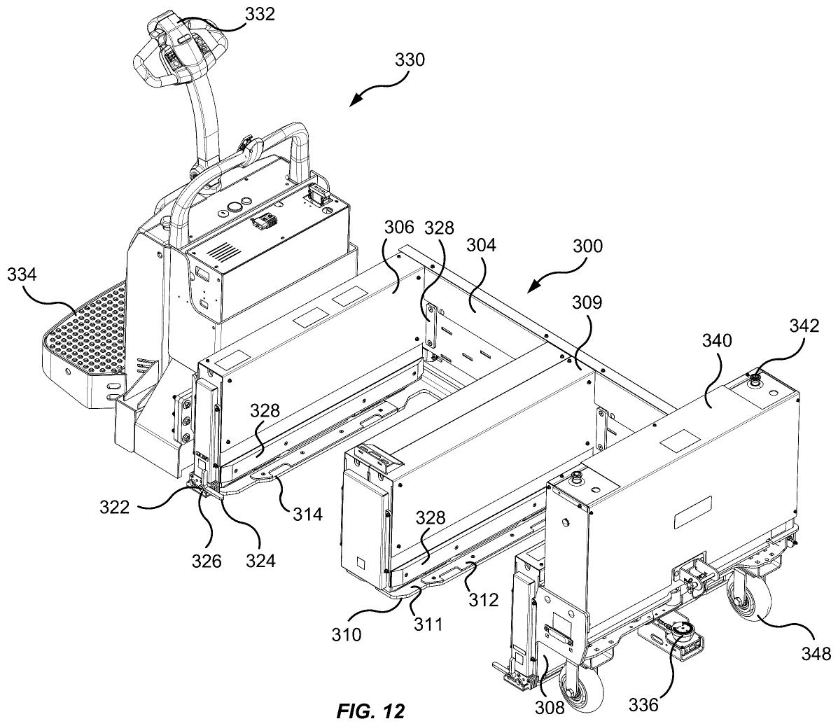

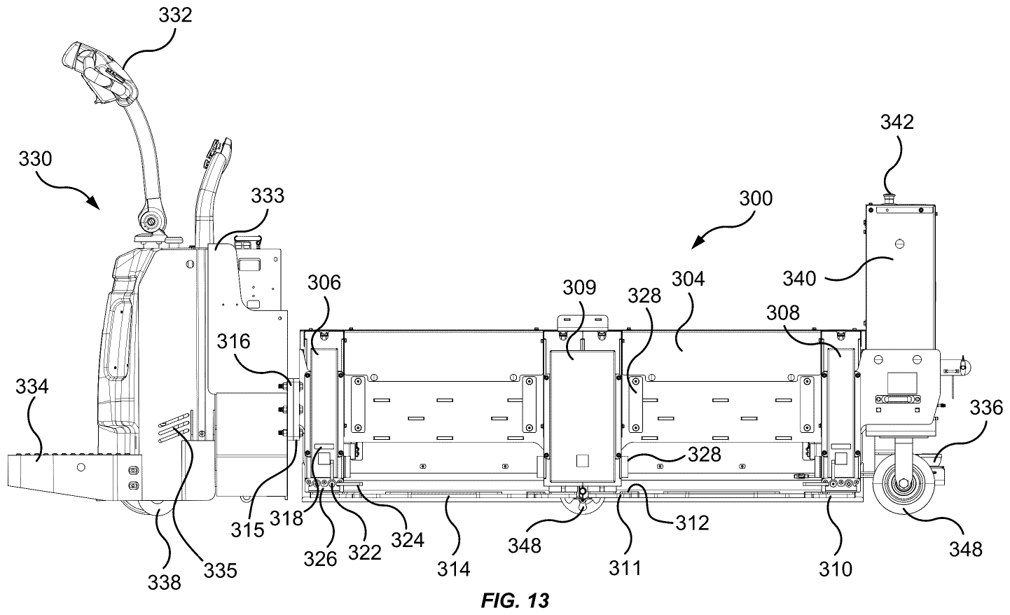

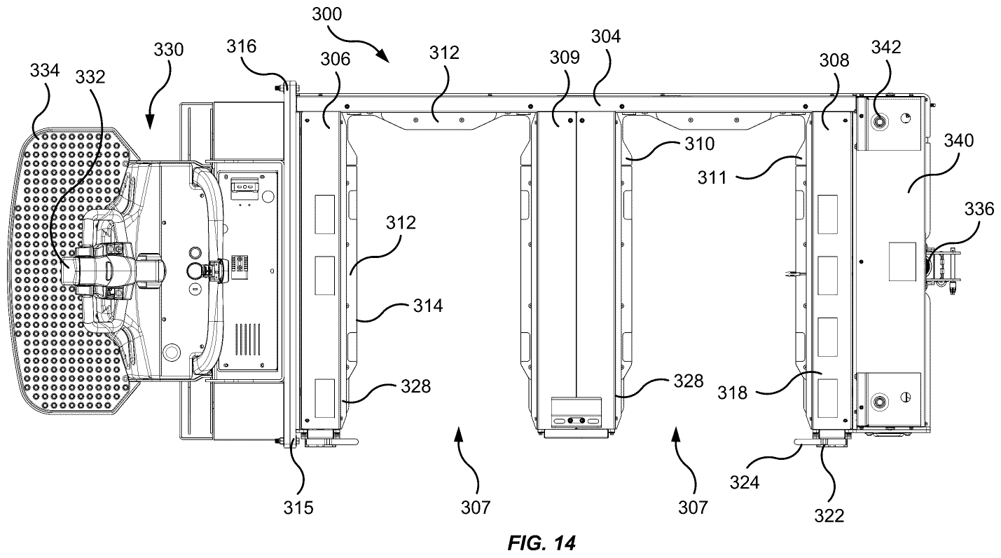

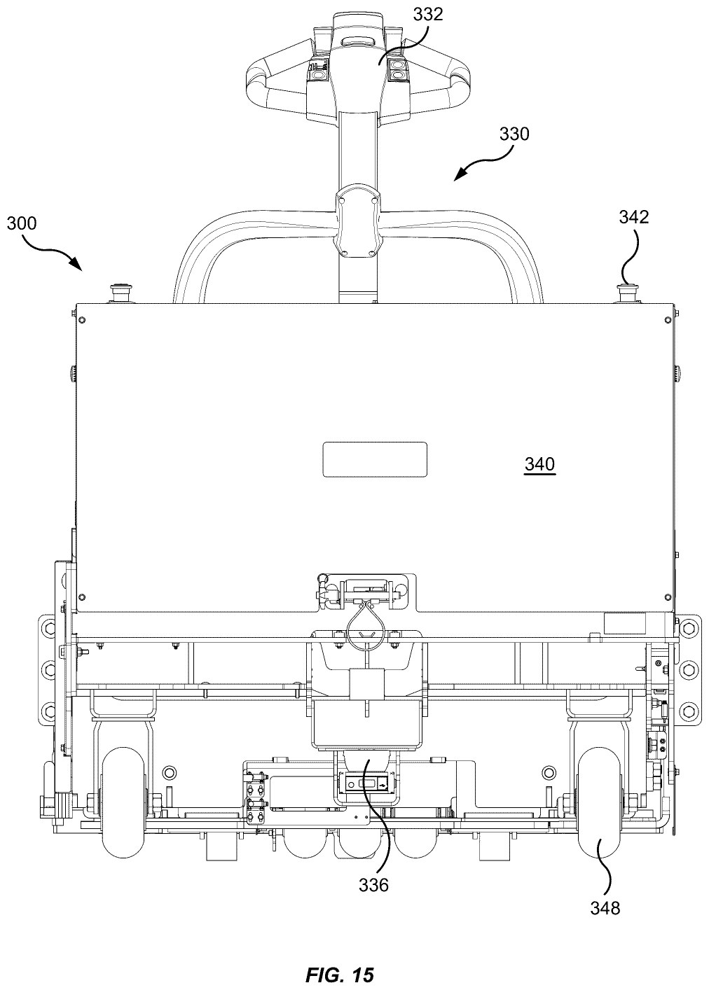

FIG. 12 is a perspective view of a lift attachment 300 attached to a lift truck 330, according to an embodiment of the present invention. FIG. 13 is a side view of the lift attachment 300 attached to the lift truck 330 shown in FIG. 12. FIG. 14 is a top view of the lift attachment 300 attached to the lift truck 330 shown in FIG. 12. FIG. 15 is a front view of the lift attachment 300 attached to the lift truck 330 shown in FIG. 12. The lift attachment 300 is shown to be part of an automated system, an autonomous system, a semi-automated system, or a semi-autonomous system. The lift attachment 300 is shown to be attached to a lift truck 330 that does not include forks.

The lift attachment 300 includes a back wall 304, a first sidewall 306, and a second sidewall 308. The lift attachment 300 can further include a divider wall 309. The divider wall 309 is disposed in between the first sidewall 306 and the second sidewall 308. The divider wall 309 and the first sidewall 306 form a first bay and the divider wall 309 and the second sidewall 308 form a second bay. Each of the first sidewall 306, the second sidewall 308, and the divider wall 309 are disposed in an upright position and substantially parallel to one another. The first sidewall 306, the second sidewall 308, and the divider wall 309 are spaced apart from one another. The first sidewall 106, the second sidewall 108, and the divider wall 309 define the first bay, the second bay, and respective entrances 307 to the first bay and second bay at a side of the lift attachment 300. The back wall 304 is secured to the first sidewall 306, the second sidewall 308, and the divider wall 309. The back wall 304 is in the upright position and substantially orthogonal to the first sidewall 306, the second sidewall 308, and the divider wall 309. The back wall 304 is situated at an opposite side of the lift attachment 300 as the entrances 307. The lift attachment 300 can further include casters 348 or wheels.

The lift attachment 300 includes more than one lift plate 310. Each of the bays include one or more lift plates 310. For the first bay, the lift plate 310 can run along the bottoms of the first sidewall 306, the back wall 304, and the divider wall 309 and for the second bay, the lift plate 310 can run along the bottoms of the divider 309, the back wall 304, and the second sidewall 308. The lift plates 310 each include a ledge 311 that extends from a bottom of the respective first sidewall 306 and second sidewall 308, the back wall 304, and the divider wall 309. The ledges 311 extend sideward into the respective bay at a substantially orthogonal direction relative to the respective first sidewall 306, the second sidewall 308, the back wall 304, and the divider wall 309. The ledges 311 each include an inner edge 314 that define openings through a bottom of the lift attachment 300 and through the entrances 307 of the lift attachment 300.

The lift plates 310 can each include at least one protective cover 312 attached to an upper surface of the respective ledges 311. As can be seen, protective covers 312 are attached to the ledge 311 adjacent to the first sidewall 306, adjacent to the divider wall 309, adjacent to the second sidewall 308, and adjacent to the back wall 304. The protective covers 312 are made of a material that is more flexible than the ledges 311. For example, the ledges 311 can be made of a metal material and the protective covers 312 can be made of a plastic or rubber material. The protective covers 312 prevent damage to the lift attachment 300 and the server racks.

The lift attachment 300 includes a connector 315 configured to connect with a lifting mechanism 333 of a lift truck 330 such that the lift attachment 300 moves up or down with the lifting mechanism 333. The connector 315 can be fixed directly to a carriage 316 of the lift truck 330.

The lift attachment 300 can further include a plurality of wall guide members 328. Wall guide members 328 can be attached to the inner surfaces of the first sidewall 306, the second sidewall 308, the divider wall 309 and the back wall 304. As can be seen, the wall guide members 328 attached to the first sidewall 306, the divider wall 309, and the second sidewall 308 can include a taper that tapers to a thinner profile towards the entrance 307. This allows a server rack, or any other type of rack, to be guided through the entrance 307 and into the respective bay. The wall guide members 328 are made of a material that is more flexible than the first sidewall 306, the second sidewall 308, the divider wall 309, and the back sidewall 304. For example, the sidewalls 306, 308 and backwall 304 can be made of a metal material and the guide members 328 can be made of a plastic or rubber material. The guide members 328 guide the racks and prevent damage to the racks and the lift attachment 300.

The lift attachment 300 can further include lock mechanisms 322. The lock mechanisms 322 can lock the server racks or other type of racks within the respective bay of the lift attachment 300. The lock mechanisms 312 can each include a gate 324 and a gate bracket 326. The gate bracket 326 can be attached to one or more of the first sidewall 306, the second sidewall 308, and the divider wall 309. The gate 324 can be pivotably secured to the gate bracket 326 and thus can pivot upwards and downwards. For example, the gate 324 can be secured to the gate bracket 326 by a bolt and can pivot about the bolt. The gate 324 can be secured to the gate bracket 326 by the bolt with some resistance to pivoting. Thus, when the gate 324 is pivoted, the gate 324 can stay in place until a threshold force is acted upon the gate 324 to pivot in the opposite direction. The gate 324 is configured to pivot from an unlocked position at which the gate 324 provides a clearance to the entrances 307, and a locked position at which the gate 324 blocks at least a portion of the entrances 307. The gate 324 can be an L-shaped member and thus can include a lever to allow the gate 324 to be easily pivoted back and forth. Each bay can have a respective lock mechanism 322.

In certain embodiments, the entire lift attachment 300 can be lifted up and down by the carriage 316 of the lift truck 330. In certain embodiments, the lift attachment 300 can include lifting mechanisms 318. The lifting mechanism 318 can be an automated lifting mechanism that is powered by a power source. The lifting mechanism 318 can include an actuator that lifts the lift plate 310 up upon the first activation and lowers the lift plate 310 down upon the second activation. The actuator can include any type of actuator, such as a hydraulic actuator, a pneumatic actuator, an electrical actuator, a magnetic actuator, a mechanical actuator, and the like, as long as the actuator is capable of lifting the lift plate 310 up and down relative to a frame of the lift attachment 300. The lifting mechanism 318 can include an actuator that actuates a sliding frame fixedly coupled to the lift plate 310 and slidably coupled to the frame of the lift attachment 300 such that the sliding frame slides vertically relative to the frame of the lift attachment 300.

The lift attachment 300 can include a control unit 340 having buttons 342. When the buttons 342 are pressed to raise the lift plate 310, a piston of the actuator extends and lifts the sliding frame relative to the frame of the lift attachment, and thereby lifts the lift plate 310 to an elevated position. When the buttons 342 are pressed to lower the lift plate 310, the piston retracts and lowers the sliding frame relative to the frame of the lift attachment, and thereby lowers the lift plate 310 from the elevated position.

The lift truck 330 can include a platform 334 and controls 332 for a person to drive and control the lift truck 330. As mentioned above, the control unit 340 can be used for the lifting mechanisms 318. In certain embodiments, the control unit 340 is utilized for autonomous movement of the lift truck 330. In such embodiments, the lift truck 330 and/or the lift attachment 300 can include sensors, i.e., a sensor system 336. The control unit 340 can include one or more processors and one or more memories. For example, the control unit 340 can include a central control unit, such as processor and a memory. The central control unit can use high-performance processors, artificial intelligence algorithms, and data fusion from the various sensors of the sensor system 336. A Sensor Fusion Unit (SFU) can integrate data from different sensors such as cameras, LiDAR, radar, and ultrasonic sensors to create a coherent view of the environment.

The control unit 340 can further include path planning and decision-making unit, which can be the processor or other processor used to determine an optimal path for the lift truck 330 and can make real-time driving decisions using artificial intelligence (AI), machine learning models, and predictive algorithms. The control unit 340 can further include an actuation control unit that directly controls the lift truck's 330 movement, including steering, braking, and acceleration of the wheels 338 by a drive train 335, using microcontrollers, control algorithms, and actuator interfaces.

Using the sensor system 336, the control unit 340 can control the drive train 335 of the lift truck 330 to navigate autonomously within a building to a pick up location and a drop off location. The control unit 340 can further autonomously control the lifting mechanism 333 of the lift truck 330 and/or the lifting mechanisms 318 of the lift attachment 300. The control unit 340 can determine whether a rack is within the bay of the lift attachment 300 at the pick-up location based on signals received from the sensor system 336, activate the lifting mechanism 333 of the lift truck 330 and/or the lifting mechanisms 318 of the lift attachment 300 such that the rack or racks are lifted to raised position above a floor of the building at the pickup location, and activate the lifting mechanism 333 of the lift truck 330 and/or the lifting mechanisms 318 of the lift attachment 300 such that the rack or racks are lowered to a lowered position onto the floor of the building at the drop off location.

The present invention includes the following aspects/embodiments/features in any order and/or in any combination:

1. A lift attachment comprising:
a first sidewall and a second sidewall, each of the first sidewall and the second sidewall being disposed in an upright position, the first sidewall and the second sidewall being spaced apart from one another, wherein the first sidewall and the second sidewall each comprise an inner surface that face one another and define a bay therebetween, the first sidewall and the second sidewall further defining an entrance at a front end of the lift attachment;
at least one lift plate comprising a ledge that extends from a bottom of the first sidewall and the second sidewall, wherein the ledge extends sideward into the bay, the ledge comprising an inner edge that defines an opening through a bottom of the lift attachment and through the entrance of the lift attachment; and
a connector configured to connect with a lifting mechanism of a lift truck such that the lift attachment moves up or down with the lifting mechanism.

2. The lift attachment of any preceding or following embodiment/feature/aspect, further comprising a back wall secured to the first sidewall and the second sidewall, the back wall being in the upright position and substantially orthogonal to the first sidewall, the second sidewall and the at least one lift plate, the back wall being situated at a rear end of the lift attachment.

3. The lift attachment of any preceding or following embodiment/feature/aspect, wherein the ledge runs along the bottoms of the first sidewall, the back wall, and the second sidewall, and defines a U-shape.

4. The lift attachment of any preceding or following embodiment/feature/aspect, further comprising a plurality of wall guide members comprising at least one first sidewall guide member attached to the inner surface of the first sidewall, at least one second sidewall guide member attached to the inner surface of the second sidewall, and at least one back wall guide member attached to an inner surface of the back wall, wherein the plurality of wall guide members are made of a material that is more flexible than a material of the first sidewall, the second sidewall, and the back sidewall.

5. The lift attachment of any preceding or following embodiment/feature/aspect, wherein the plurality of guide members are made of a plastic or rubber material.

6. The lift attachment of any preceding or following embodiment/feature/aspect, wherein the at least one lift plate further comprises at least one protective cover attached to an upper surface of the ledge.

7. The lift attachment of any preceding or following embodiment/feature/aspect, wherein the at least one protective cover is made of a metal material.

8. The lift attachment of any preceding or following embodiment/feature/aspect, further comprising a lock mechanism comprising a gate pivotably coupled to a gate bracket, wherein the gate is configured to pivot from an unlocked position at which the gate provides a clearance to the entrance, and a locked position at which the gate blocks at least a portion of the entrance.

9. The lift attachment of any preceding or following embodiment/feature/aspect, wherein the connector is configured to attach to a fork of a powered forklift or a manual forklift.

10. The lift attachment of any preceding or following embodiment/feature/aspect, wherein the connector comprises a first fork sleeve secured to the first sidewall and a second fork sleeve secured to the second sidewall, each of the first fork sleeve and the second fork sleeve comprise an opening leading to a hollow center sized to receive a respective fork tine of the fork.

11. The lift attachment of any preceding or following embodiment/feature/aspect, wherein the first fork sleeve is disposed at a bottom of the first sidewall and the second fork sleeve is disposed at a bottom of the second sidewall, and an upper surface of the ledge is disposed beneath the first fork sleeve and the second fork sleeve.

12. The lift attachment of any preceding or following embodiment/feature/aspect, further comprising a first plurality of angle brackets connecting an upper surface of the first fork sleeve to an outer surface of the first sidewall and a second plurality of angle brackets connecting an upper surface of the second fork sleeve to an outer surface of the second sidewall.

13. The lift attachment of any preceding or following embodiment/feature/aspect, further comprising a divider wall disposed in between the first sidewall and the second sidewall, wherein the divider wall and the first sidewall form the bay and the divider wall and the second sidewall form a second bay.

14. The lift attachment of any preceding or following embodiment/feature/aspect, wherein a width of the bay is adjustable.

15. The lift attachment of any preceding or following embodiment/feature/aspect, wherein a length of the bay is adjustable.

16. The lift attachment of any preceding or following embodiment/feature/aspect, wherein the at least one lift plate is adjustable to extend towards a center of the bay and to retract away from the center of the bay.

17. The lift attachment of any preceding or following embodiment/feature/aspect, wherein the at least one lift plate is removably secured to the lift attachment such that the at least one lift plate is configured to be removed and replaced with a different sized lift plate.

18. A lift truck comprising a lifting mechanism, wherein the connector of the lift attachment of any preceding or following embodiment/feature/aspect is connected to the lifting mechanism.

19. The lift truck of any preceding or following embodiment/feature/aspect, wherein the lift truck is a fork lift and the fork lift is a powered forklift or a manual forklift.

20. An autonomous lift truck comprising the lift attachment of any preceding or following embodiment/feature/aspect, comprising:
a drive train for moving the autonomous lift truck;
a lifting mechanism of the autonomous lift truck, which is secured to the connector of the lift attachment;
a control unit configured to autonomously control the drive train based on signals received; and
a sensor system configured to sense objects and send signals to the control unit;
wherein the drive train is configured to be controlled by the control unit to navigate autonomously within a building to a pick-up location and a drop off location.

21. The autonomous lift truck of any preceding or following embodiment/feature/aspect, wherein the sensor system is operatively connected to the lift attachment and the control unit is further configured to autonomously control the lifting mechanism, wherein the control unit (1) determines whether a rack is within the bay of the lift attachment at the pick-up location based on signals received from the sensor system; (2) activates the lifting mechanism such that the lift attachment elevates the rack to a raised position above a floor of the building at the pick up location; and (3) activates the lifting mechanism such that the lift attachment lowers the rack to a lowered position onto the floor of the building at the drop off location.

22. The autonomous lift truck of any preceding or following embodiment/feature/aspect, wherein the lift attachment further comprises a lock mechanism comprising a gate pivotably coupled to a gate bracket, wherein the gate is configured to pivot from an unlocked position at which the gate provides a clearance to the entrance, and a locked position at which the gate is pivoted towards the entrance and blocking at least a portion of the entrance.

23. The autonomous lift truck of any preceding or following embodiment/feature/aspect, wherein the locking mechanism comprises an automated system electrically connected to a power source and the automated system is controlled by the control unit, wherein, at the pick-up location, when the control unit determines the rack is within the bay of the lift attachment, the control unit activates the locking mechanism to the locked position and when the control unit determines the autonomous lift truck is at the drop-off location and the lifting mechanism lowers the rack to the lowered position, the control unit activates the locking mechanism to the unlocked position.

24. A method of transporting a server rack within an industrial setting comprising:
attaching a lift attachment to a lifting mechanism of a lift truck, the lift attachment comprising a first sidewall, a second sidewall, and at least one lift plate comprising a ledge that extends from a bottom of the first sidewall and the second sidewall into a bay defined in between the first sidewall and the second sidewall;
rolling a server rack comprising wheels into the bay of the lift attachment such that an outer perimeter of a bottom of the server rack is disposed above the ledge;
raising the lifting mechanism of the lift truck such that the ledge of the lift attachment engages the perimeter of the bottom of the server rack and the wheels of the server rack are elevated above a floor of the industrial setting; and
driving the lift truck and thereby transporting the server rack to a different location within the industrial setting.

The entire contents of all references cited in this disclosure are incorporated herein in their entireties, by reference. Further, when an amount or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether such a range is separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

What is claimed is:

1. A lift attachment comprising:
a first sidewall and a second sidewall, each of the first sidewall and the second sidewall being disposed in an upright position, the first sidewall and the second sidewall being spaced apart from one another, wherein the first sidewall and the second sidewall each comprise an inner surface that face one another and define a bay therebetween, the first sidewall and the second sidewall further defining an entrance at a front end of the lift attachment;
at least one lift plate comprising a ledge that extends from a bottom of the first sidewall and the second sidewall, wherein the ledge extends sideward into the bay, the ledge comprising an inner edge that defines an opening through a bottom of the lift attachment and through the entrance of the lift attachment; and
a connector configured to connect with a lifting mechanism of a lift truck such that the lift attachment moves up or down with the lifting mechanism.

2. The lift attachment of claim 1, further comprising a back wall secured to the first sidewall and the second sidewall, the back wall being in the upright position and substantially orthogonal to the first sidewall, the second sidewall and the at least one lift plate, the back wall being situated at a rear end of the lift attachment.

3. The lift attachment of claim 2, wherein the ledge runs along the bottoms of the first sidewall, the back wall, and the second sidewall, and defines a U-shape.

4. The lift attachment of claim 2, further comprising a plurality of wall guide members comprising at least one first sidewall guide member attached to the inner surface of the first sidewall, at least one second sidewall guide member attached to the inner surface of the second sidewall, and at least one back wall guide member attached to an inner surface of the back wall, wherein the plurality of wall guide members are made of a material that is more flexible than a material of the first sidewall, the second sidewall, and the back sidewall.

5. The lift attachment of claim 4, wherein the plurality of guide members are made of a plastic or rubber material.

6. The lift attachment of claim 1, wherein the at least one lift plate further comprises at least one protective cover attached to an upper surface of the ledge.

7. The lift attachment of claim 6, wherein the at least one protective cover is made of a metal material.

8. The lift attachment of claim 1, further comprising a lock mechanism comprising a gate pivotably coupled to a gate bracket, wherein the gate is configured to pivot from an unlocked position at which the gate provides a clearance to the entrance, and a locked position at which the gate blocks at least a portion of the entrance.

9. The lift attachment of claim 1, wherein the connector is configured to attach to a fork of a powered forklift or a manual forklift.

10. The lift attachment of claim 9, wherein the connector comprises a first fork sleeve secured to the first sidewall and a second fork sleeve secured to the second sidewall, each of the first fork sleeve and the second fork sleeve comprise an opening leading to a hollow center sized to receive a respective fork tine of the fork.

11. The lift attachment of claim 10, wherein the first fork sleeve is disposed at a bottom of the first sidewall and the second fork sleeve is disposed at a bottom of the second sidewall, and an upper surface of the ledge is disposed beneath the first fork sleeve and the second fork sleeve.

12. The lift attachment of claim 10, further comprising a first plurality of angle brackets connecting an upper surface of the first fork sleeve to an outer surface of the first sidewall and a second plurality of angle brackets connecting an upper surface of the second fork sleeve to an outer surface of the second sidewall.

13. The lift attachment of claim 1, further comprising a divider wall disposed in between the first sidewall and the second sidewall, wherein the divider wall and the first sidewall form the bay and the divider wall and the second sidewall form a second bay.

14. The lift attachment of claim 1, wherein a width of the bay is adjustable.

15. The lift attachment of claim 1, wherein a length of the bay is adjustable.

16. The lift attachment of claim 1, wherein the at least one lift plate is adjustable to extend towards a center of the bay and to retract away from the center of the bay.

17. The lift attachment of claim 1, wherein the at least one lift plate is removably secured to the lift attachment such that the at least one lift plate is configured to be removed and replaced with a different sized lift plate.

18. A lift truck comprising a lifting mechanism, wherein the connector of the lift attachment of claim 1 is connected to the lifting mechanism.

19. The lift truck of claim 18, wherein the lift truck is a fork lift and the fork lift is a powered forklift or a manual forklift.

20. An autonomous lift truck comprising the lift attachment of claim 1, comprising:
a drive train for moving the autonomous lift truck;
a lifting mechanism of the autonomous lift truck, which is secured to the connector of the lift attachment;
a control unit configured to autonomously control the drive train based on signals received; and
a sensor system configured to sense objects and send signals to the control unit;
wherein the drive train is configured to be controlled by the control unit to navigate autonomously within a building to a pick-up location and a drop off location.

21. The autonomous lift truck of claim 20, wherein the sensor system is operatively connected to the lift attachment and the control unit is further configured to autonomously control the lifting mechanism, wherein the control unit (1) determines whether a rack is within the bay of the lift attachment at the pick-up location based on signals received from the sensor system; (2) activates the lifting mechanism such that the lift attachment elevates the rack to a raised position above a floor of the building at the pick up location; and (3) activates the lifting mechanism such that the lift attachment lowers the rack to a lowered position onto the floor of the building at the drop off location.

22. The autonomous lift truck of claim 20, wherein the lift attachment further comprises a lock mechanism comprising a gate pivotably coupled to a gate bracket, wherein the gate is configured to pivot from an unlocked position at which the gate provides a clearance to the entrance, and a locked position at which the gate is pivoted towards the entrance and blocking at least a portion of the entrance.

23. The autonomous lift truck of claim 22, wherein the locking mechanism comprises an automated system electrically connected to a power source and the automated system is controlled by the control unit, wherein, at the pick-up location, when the control unit determines the rack is within the bay of the lift attachment, the control unit activates the locking mechanism to the locked position and when the control unit determines the autonomous lift truck is at the drop-off location and the lifting mechanism lowers the rack to the lowered position, the control unit activates the locking mechanism to the unlocked position.

24. A method of transporting a server rack within an industrial setting comprising:
attaching a lift attachment to a lifting mechanism of a lift truck, the lift attachment comprising a first sidewall, a second sidewall, and at least one lift plate comprising a ledge that extends from a bottom of the first sidewall and the second sidewall into a bay defined in between the first sidewall and the second sidewall;
rolling a server rack comprising wheels into the bay of the lift attachment such that an outer perimeter of a bottom of the server rack is disposed above the ledge;
raising the lifting mechanism of the lift truck such that the ledge of the lift attachment engages the perimeter of the bottom of the server rack and the wheels of the server rack are elevated above a floor of the industrial setting; and
driving the lift truck and thereby transporting the server rack to a different location within the industrial setting.
